(19) United States
(12) Patent Application Publication
(10) Pub. No.: US 2024/0096920 A1
(43) Pub. Date: Mar. 21, 2024

(54) SENSOR ASSEMBLY AND METHOD FOR FORMING THE SAME

(71) Applicant: STATS ChipPAC Pte. Ltd., Singapore (SG)

(72) Inventors: MyungHo JUNG, gyeonggi-do (KR); SangHyun SON, Seoul (KR); YoungUk NOH, Seoul (KR); BumRyul MAENG, Incheon (KR)

(21) Appl. No.: 18/459,014

(22) Filed: Aug. 30, 2023

(30) Foreign Application Priority Data
Sep. 16, 2022 (CN) 202211132176.3

(51) Int. Cl. H01L 27/146

(52) U.S. Cl. CPC H01L 27/14636; H01L 27/14618; H01L 27/14621; H01L 27/14632; H01L 27/14685; H01L 27/14687

(57) ABSTRACT

Provided is a sensor assembly, comprising: a sensor, wherein the sensor comprises a sensor front surface comprising a sensor area and an interconnect area; at least one filter layer formed on top of the sensor front surface, wherein the at least one filter layer covers and is in direct contact with the sensor area of the sensor; a first encapsulant layer formed on top of the at least one filter layer, wherein the first encapsulant layer is transmissive to light; and wherein the interconnect area is at least partially exposed from the at least one filter layer and the first encapsulant layer.

### TECHNICAL FIELD

The present application generally relates to sensor technologies, and more particularly, to a sensor assembly and a method for forming a sensor assembly.

### BACKGROUND OF THE INVENTION

Sensors are widely used in electronic devices to detect signals from exterior environment. Especially in real-time applications such as advanced driver assistance systems (ADAS), artificial intelligence systems and drones, sensors play an important role in providing reliable and accurate data for the overall system. Yet, a conventional sensor assembly structure may have reliability issue. For example, in a conventional optical sensor manufactured with a lid attach process, there exists risk such as delamination between liquid crystal polymer (LCP) lid and adhesive. Also, a clear mold used for encapsulation has a high shrinkage rate, which may cause a curved neck portion of a lead encapsulated in the clear mold to undesirably break in a molding process.

Therefore, a need exists for an improved sensor assembly.

### SUMMARY OF THE INVENTION

An objective of the present application is to provide a sensor assembly with an improved reliability.

According to one aspect of the present application, a sensor assembly is provided, comprising: a sensor, wherein the sensor comprises a sensor front surface comprising a sensor area and an interconnect area; at least one filter layer formed on top of the sensor front surface, wherein the at least one filter layer covers and is in direct contact with the sensor area of the sensor; a first encapsulant layer formed on top of the at least one filter layer, wherein the first encapsulant layer is transmissive to light; and wherein the interconnect area is at least partially exposed from the at least one filter layer and the first encapsulant layer.

According to another aspect of the present application, an electronic device is provided, comprising: a substrate comprising a substrate front surface and a set of conductive pads on the substrate front surface; a sensor assembly mounted on the substrate front surface, the sensor assembly comprising: a sensor, wherein the sensor comprises a sensor front surface comprising a sensor area and an interconnect area; at least one filter layer formed on top of the sensor front surface, wherein the at least one filter layer covers and is in direct contact with the sensor area of the sensor; a first encapsulant layer formed on top of the at least one filter layer, wherein the first encapsulant layer is transmissive to light; and wherein the interconnect area is at least partially exposed from the at least one filter layer and the first encapsulant layer; a set of connection wires for electrically connecting the set of conductive pads with the interconnect area, respectively; and a second encapsulant layer formed on top of the substrate for encapsulating the sensor assembly and the set of connection wires.

According to another aspect of the present application, a method for forming a sensor assembly is provided, comprising: providing a sensor, wherein the sensor comprises a sensor front surface comprising a sensor area and an interconnect area; forming a patterned photoresist layer on the sensor front surface, wherein the patterned photoresist layer at least partially covers the interconnect area of the sensor but exposes the sensor area; forming at least one filter layer on top of the sensor front surface, wherein the at least one filter layer covers and is in direct contact with the sensor area of the sensor and the patterned photoresist layer; forming a first encapsulant layer on top of the at least one filter layer, wherein the first encapsulant layer is transmissive to light; and removing a portion of the first encapsulant layer, a portion of the at least one filter layer and the patterned photoresist layer to at least partially expose the interconnect area.

According to another aspect of the present application, a method for forming an electronic device is provided, comprising: providing a substrate comprising a substrate front surface and a set of conductive pads on the substrate front surface; providing a sensor, wherein the sensor comprises a sensor front surface comprising a sensor area and an interconnect area; forming a patterned photoresist layer on the sensor front surface, wherein the patterned photoresist layer at least partially covers the interconnect area of the sensor but exposes the sensor area; forming at least one filter layer on top of the sensor front surface, wherein the at least one filter layer covers and is in direct contact with the sensor area of the sensor and the patterned photoresist layer; forming a first encapsulant layer on top of the at least one filter layer, wherein the first encapsulant layer is transmissive to light; removing a portion of the first encapsulant layer, a portion of the at least one filter layer and the patterned photoresist layer to at least partially expose the interconnect area; mounting the sensor on the substrate front surface; forming a set of connection wires to electrically connect the set of conductive pads with the interconnect area, respectively; and forming a second encapsulant layer on top of the substrate to encapsulate the sensor, the at least one filter layer, the first encapsulant layer and the set of connection wires.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a cross-sectional view of a sensor assembly according to an embodiment of the present application.

FIG. 2 illustrates a flowchart of a method for forming a sensor assembly according to an embodiment of the present application.

FIGS. 3A-3F illustrate cross-sectional views of steps of the method shown in FIG. 2 for forming a sensor assembly according to an embodiment of the present application.

FIG. 4 illustrates a cross-sectional view of an electronic device according to an embodiment of the present application.

FIG. 5 illustrates a cross-sectional view of an electronic device according to another embodiment of the present application.

FIG. 6 illustrates a cross-sectional view of an electronic device according to another embodiment of the present application.

FIG. 7 illustrates a flowchart of a method for forming an electronic device shown in FIG. 4 according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Sensors may be integrated with other electronic components to detect signals in exterior environment. Specifically, some applications such as autonomous cars, in-display fingerprint scanners and secure facial recognition require optical signals such as ambient, infrared (IR) and ultraviolet (UV) lights to assist the system in making decisions. Within the lights of various wavelengths irradiating to the sensors, lights of certain wavelengths may be specifically required. Therefore, an optical sensor system is usually equipped with filters for filtering lights, sensors for converting optical signals into electrical signals, and optionally, other electronic components for further calculating based on the electrical signals. According to some embodiments of the present application, a sensor assembly is provided. The sensor assembly is designed to provide optical filtering function with reliability.

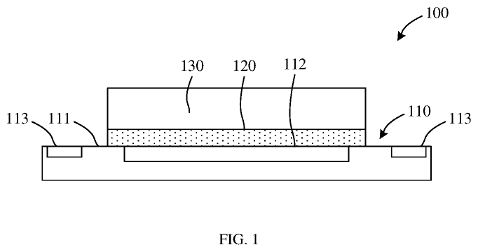

FIG. 1 illustrates a sensor assembly 100 according to an embodiment of the present application. In the embodiment, the sensor assembly 100 is an optical sensor assembly such as a camera assembly or an infrared red sensor assembly, which is used to detect lights from the environment.

Referring to FIG. 1, the sensor assembly 100 includes a sensor 110, at least one filter layer 120 and a first encapsulant layer 130 laminated on the sensor 110. The sensor 110 may be a semiconductor die that is manufactured using semiconductor microfabrication technologies. In particular, the sensor 110 includes a sensor front surface 111, and the sensor front surface 111 includes a sensor area 112 and an interconnect area 113. In some embodiments, the sensor area 112 may be photosensitive, and may take the form of a light conversion array including a plurality of photoelectric conversion elements. The interconnect area 113 does not overlap with the sensor area 112, and is used to electrically connect the sensor 110 with other electronic components via such as wire bond. That is, wire bonds can be bonded onto the interconnect area 113 which serves as a bonding area for the sensor 110. Note that the layout of the sensor area 112 and the interconnect area 113 is only illustrative, not representing the actual form of the areas. Preferably, the sensor area 112 is at the center of the sensor front surface 111 and occupies a majority of the sensor front surface 111. The interconnect area 113 is outside the sensor area 112, e.g., at or close to the periphery of the sensor front surface 111 and surrounds the sensor area 112. It can be understood that, in such configuration, the interconnect area 113 surrounding the sensor area 112 may form a ring from a top view. However, in some other embodiments, the interconnect area 113 may be formed at only one, two or three sides of the sensor area 112, rather than entirely surrounding the sensor area 112. In some other embodiments, the interconnect area 113 may specifically include at least one conductive pads (not shown) for wire bonding.

On top of the sensor area 112, at least one filter layer 120 is formed, which at least partially covers the sensor area 112 and is in direct contact with the sensor area 112. In some embodiments, the at least one filter layer 120 may take a shape similar to the shape of the sensor area 112, and may fully cover the sensor area 112 to uniformly filter out undesired light wavelengths that are emitted towards the sensor area 112 from external environment. Preferably, the at least one filter layer includes an optical filter film, which may selectively allow light of a certain wavelength range (smaller/larger than a wavelength, within a wavelength range, at a wavelength, etc.) to pass through. For example, the optical filter film may be thin-film optical filters of alternating thin layers of materials with special optical properties. The optical filter film may transmit, block or reflect light of different wavelength ranges. The optical filter film can be a bandpass filter, a notch filter, a shortpass edge filter, a longpass edge filter, a dichroic filter or a customized filter matching arbitrary ranges of wavelengths. Preferably, the optical filter film may be formed via a coating process. It can be appreciated that the optical filter film may be any optical filter film that is suitable for filtering lights for a sensor. It can also be appreciated that the at least one filter layer 120 may include multiple filter layers having different optical properties. It can also be appreciated that a thickness of the at least one filter layer 120 may vary according to the design and function of the overall sensor assembly.

Further referring to FIG. 1, on top of the at least one filter layer 120, a first encapsulant layer 130 which is transmissive to light is formed, such that light from the exterior environment may pass through the first encapsulant layer 130, be partially filtered by the filter layer 120, and reach the sensor area 112. In some embodiments, the at least one filter layer 120 aligns vertically with the first encapsulant layer 130 due to the specific process for forming them, which will be elaborated below with more details. In some embodiments, the first encapsulant layer 130 includes a clear epoxy molding material such as a clear epoxy resin. In some other embodiments, the first encapsulant layer 130 may include other transparent encapsulant material such as infrared epoxy molding compound. The first encapsulant layer 130 may optionally include curing agent (hardener). The first encapsulant layer 130 can be formed by coating, spraying, or inkjet depositing a liquid encapsulant material onto the at least one filter layer 120. The first encapsulant layer 130 can be non-conductive, provides structural support, and environmentally protects the sensor area 112 of the sensor 110 and the at least one filter layer 120 from external elements and contaminants. It can also be appreciated that a thickness of the first encapsulant layer 130 may vary according to the design and function of the overall sensor assembly.

As no clear mold is formed above the interconnect area 113, or at least other lead or wire friendly molding materials may be used for encapsulating the wires or leads to be attached to the interconnect area 113, the risk that the leads or wires attached onto the interconnect area 113 undesirably break in a subsequent molding process can be reduced. Also, since the sensor area 112 and the above filter layer 120 can be protected by the first encapsulant layer 130, no lid is further desired on top of the filter layer 120 for protection purpose. As such, the sensor assembly 100 can be formed with other identical or similar sensor assemblies using a wafer-level process, as elaborated below.

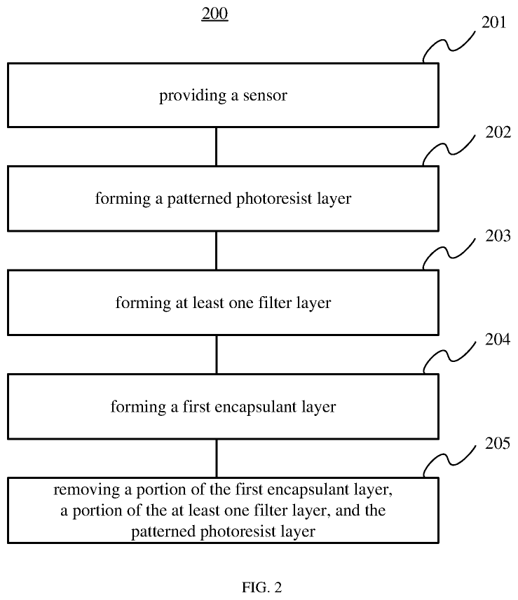

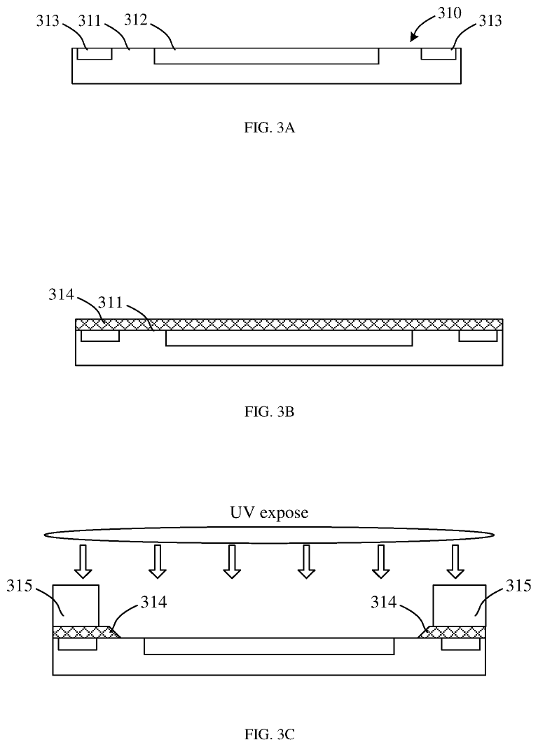

FIG. 2 illustrates a flowchart of a method 200 for forming a sensor assembly according to an embodiment of the present application. FIGS. 3A-3F illustrate cross-sectional views of steps of the method 200 according to an embodiment of the present application.

As shown in FIG. 2 and FIG. 3A, the method 200 starts with step 201 of providing a sensor. In FIG. 3A, similar to the sensor 110 shown in FIG. 1, sensor 310 includes a sensor front surface 311, and the sensor front surface 311 includes a sensor area 312 and an interconnect area 313. It can be appreciated that the sensor 310 may not be individual sensor chips that have already been singulated from a sensor wafer. Rather, the sensor 310 may be one sensor formed in a sensor wafer, with other identical or similar sensors. That is, the method 200 or at least most steps thereof may be implemented as a wafer level process.

Then, as shown in step 202, a patterned photoresist layer is formed on the sensor front surface 311, and the patterned photoresist layer at least partially covers the interconnect area 313 of the sensor 310 but exposes the sensor area 312. In step 202, the patterned photoresist layer can be formed using an ultraviolet (UV) lithography process which is illustrated in FIGS. 3B and 3C. Specifically, as shown in FIG. 3B, a photoresist layer 314 fully covering the sensor front surface 311 is formed on top of the sensor front surface 311. For example, the photoresist layer 314 can be formed using printing, spin coating, or spray coating. Then the photoresist layer 314 is formed with certain pattern using such as a lithography process. For example, as shown in FIG. 3C, the photoresist layer 314 may be a positive photoresist layer, and a set of positions 314 of the photoresist layer desired to be remained may be covered or shielded by a mask 315 with a desired pattern. Then, the overall structure is exposed to UV light, and the exposed portions of the photoresist layer may be later removed with such as a developer while the covered portions of the photoresist layer may be remained after the development process. In some other embodiments, the photoresist layer may be a negative photoresist layer, and a mask covering the positions desired to be removed needs to be configured, which is exactly the opposite to the embodiment shown in FIG. 3C. Ideally, the edge of the photoresist pattern may be vertical to the covered surface. Yet in some cases, slopes may occur at the edge of the photoresist pattern owing to the gradual decrease of light intensity through absorption in photoresist during UV exposure, and the portion of photoresist closest to the surface is exposed by the highest intensity of light but and the bottom part is exposed at the least intensity. As such, upon photoresist development, the positive photoresist may give a positive slope of photoresist profile along the edge of the opening, as shown in FIG. 3C.

Further referring to FIG. 2 and FIG. 3D, in step 203, at least one filter layer 320 is formed on top of the sensor front surface 311. The at least one filter layer 320 covers and is in direct contact with the sensor area 312 of the sensor 310 and the patterned photoresist layer 314. Preferably, the at least one filter layer 320 fully covers the exposed portion of the sensor area 312 and the patterned photoresist layer 314. The configuration of the at least one filter layer 320 can refer to the illustration of the at least one filter layer 120 shown in FIG. 1.

Then, in step 204 and FIG. 3E, a first encapsulant layer 330 is formed on top of the at least one filter layer 320, wherein the first encapsulant layer 330 is transmissive to light to avoid undesired light screening for the sensor below. The configuration of the first encapsulant layer 330 can be referred to the illustration of the at least one filter layer 130 shown in FIG. 1. Preferably, the first encapsulant layer 330 may entirely cover the at least one filter layer 320. Preferably, the first encapsulant layer 330 is configured to protect a sensor underneath from external impact or damage. In addition, preferably, the first encapsulant layer 330 is transmissive to light without any filtering effect. It can be appreciated that a thickness of the photoresist layer 314, the at least one filter layer 320 and a thickness of the first encapsulant layer 330 may vary according to design and function of the present application.

Further referring to FIG. 2 and FIG. 3F, in step 205, a portion of the first encapsulant layer 330, a portion of the at least one filter layer 320 and the patterned photoresist layer 314 are removed, so as to at least partially expose the interconnect area 313. In some embodiments, the removal may adopt a half-cut process performed with a saw or a laser cutting tool. The position where the half-cut process is performed is configured such that the interconnect area 313 is at least partially exposed after the half-cut process. A depth of the half-cut process may be equal to or larger than a total thickness of the first encapsulant layer 330 and the at least one filter layer 320, yet smaller than the total thickness of the first encapsulant layer 330, the at least one filter layer 320 and the patterned photoresist layer 314. In some embodiments where the depth of the half-cut process is smaller than the total thickness of the first encapsulant layer 330, the at least one filter layer 320 and the patterned photoresist layer 314, some patterned photoresist layer 314 is remained. In other words, the patterned photoresist layer 314 may not be fully removed so that the remaining photoresist layer 314 can protect the interconnect area thereunder from damage during the half-cut process. The remaining patterned photoresist layer 314 may be removed later with a photoresist stripping process such as organic stripping, inorganic stripping or dry stripping. After performing the steps shown in FIG. 2, a sensor assembly shown in FIG. 1 can be obtained. It can be appreciated that if the sensor is manufactured with other similar sensors on the same wafer, a singulation process may be performed to separate these sensors from each other, which will not be elaborated herein.

Compared to the conventional sensor assembly structure and the method for forming the same, the present application preferably replaces the combination of LCP lid and adhesive with coated filter layer, and reduces the risk of delamination brought by the adhesive.

The sensor assembly of the above-mentioned structure or formed with the above-mentioned method may be integrated with other electronic components to form an electronic device.

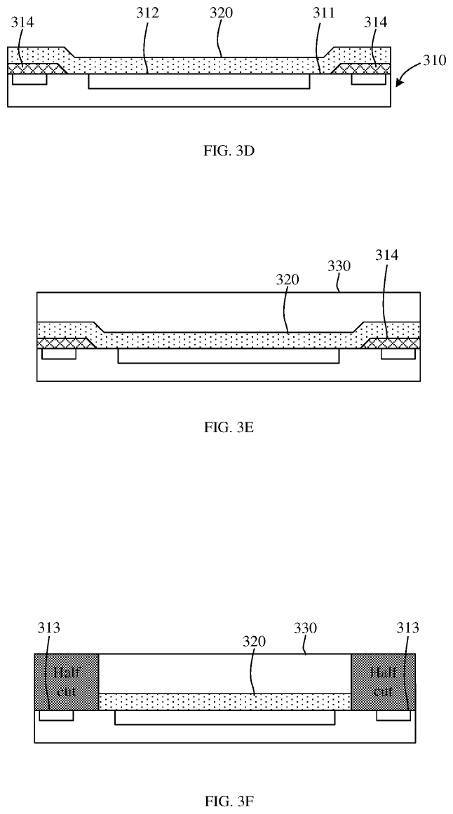

FIG. 4 illustrates a cross-sectional view of an electronic device 400 according to an embodiment of the present application.

Referring to FIG. 4, the electronic device 400 includes a sensor assembly 401, a substrate 440, a set of connection wires 450 and a second encapsulant layer 460. The substrate 440 includes a substrate front surface 441 and a set of conductive pads 442 on the substrate front surface 441. As shown in FIG. 4, in some embodiments, the substrate 440 includes interconnect structures within the substrate 440 which are electrically connected to the conductive pads 442 on the substrate front surface 441. Aspects of the present application are not limited thereto. It can be appreciated that the substrate 440 may be a plate without interconnect structure within the plate. It can be appreciated that the substrate 440 may also accommodate other electronic components mounted thereon. The structure and material of the sensor assembly 401 can be referred to the above illustration of the sensor assembly 100 shown in FIG. 1 which will not be elaborated herein.

In some embodiments, interconnect area 413 of the sensor 410 may take the form of a set of conductive pads. A set of conductive pads 413 of the sensor 410 which are distributed in the interconnect area are electrically connected to the set of conductive pads 442 on the substrate 440 via the set of connection wires 450, respectively. On top of the substrate 440, a second encapsulant layer 460 is formed encapsulating the sensor assembly 401 and the set of connection wires 450. In some embodiments, the second encapsulant layer 460 may fully cover the sensor assembly 401. Preferably, the second encapsulant layer 460 may expose a top surface of a first encapsulant layer 430, such that light can directly irradiate onto the first encapsulant layer 430. Preferably, the second encapsulant layer 460 is of a material different from the first encapsulant layer 430. In some embodiments, the second encapsulant layer 460 can be polymer composite material, such as epoxy resin, epoxy acrylate, or any suitable polymer with or without filler. The second encapsulant layer 460 can be non-conductive, provides structural support, and environmentally protects the electronic device 400 from external elements and contaminants. The second encapsulant layer 460 can be deposited on the substrate 440 using any suitable processes such as paste printing, compressive molding, transfer molding, liquid encapsulant molding, vacuum lamination, film assist molding (FAM), or spin coating.

As a person skilled in the art may understand, different molding material may have different properties. A clear molding material may provide better light transmissive effect, yet the shrinkage effect may be rather high, such as a shrinkage rate at approximately 1.3%. In contrast, a regular molding material may provide less shrinkage effect, such as a shrinkage rate at approximately 0.3%, yet not transmissive to light. Instead of encapsulating both the connection wires and the sensor area with clear mold as in conventional electronic devices, the present application encapsulates the sensor area with clear molding material and the connection wires with regular molding material with smaller shrinkage effect. Thereby, the present application resolves the risk that a curved portion of the connection wires may break due to the high shrinkage effect of a clear molding material, and the reliability of the electronic device can be improved.

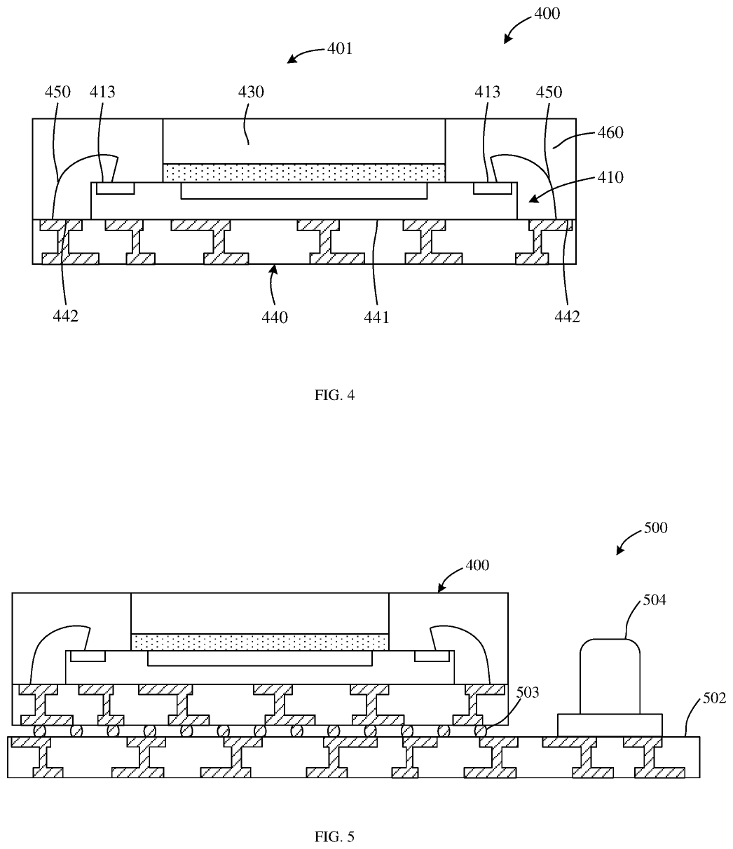

FIG. 5 illustrates another electronic device 500 integrated with the electronic device 400 illustrated above with reference to FIG. 4. Specifically speaking, the electronic device 500 includes a mother board 502, the electronic device 400 and at least one electronic component 504 mounted on the mother board 502. In some embodiments as shown in FIG. 5, an interconnect structure 503 electrically connects the mother board 502 and the electronic device 400. The interconnect structure 503 may be preferably a plurality of solder balls. In some electronic devices, the at least one electronic component 504 may include a light source, and the electronic device 500 may serve as a time of flight (ToF) system.

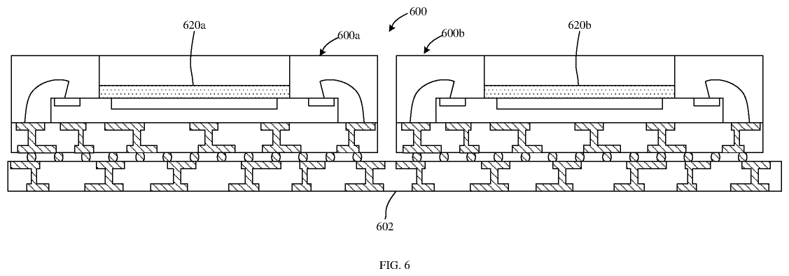

FIG. 6 illustrates another electronic device 600 integrated with two electronic devices 600a, 600b, each of which has the same structure as the electronic device 400 illustrated above with reference to FIG. 4. Specifically speaking, the electronic device 600 includes a mother board 602, and the electronic devices 600a, 600b are mounted on the mother board 602 via such as solder balls. In some embodiments, the electronic devices 600a and 600b are equipped with different filter layers 620a and 620b. The different filter layers 620a and 620b may be used to filter out light in different ranges, for example. Therefore, the electronic devices 600a and 600b may detect light of different wavelengths, and the electronic device 600 may serve as a multi-light detector. Aspects of the present application are not limited thereto. It can be appreciated that the two electronic devices 600a and 600b may be identical, therefore, under the circumstance that one electronic device malfunctions, the other electronic device and the electronic device 600 may still function normally, thereby the present application may provide improved stability.

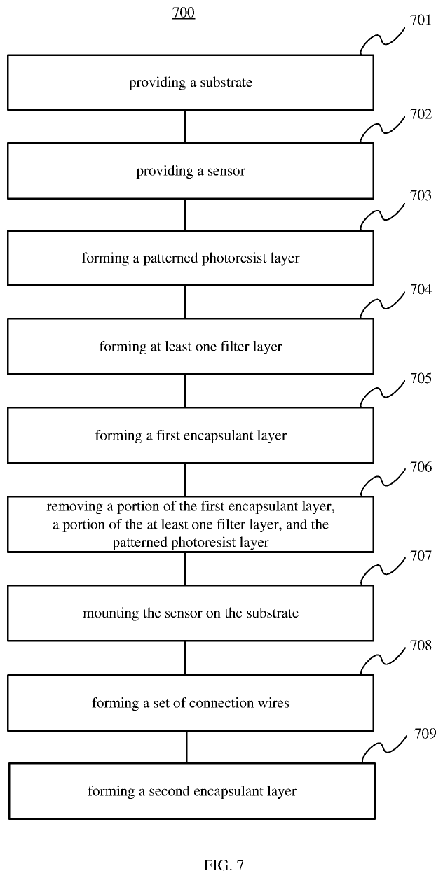

FIG. 7 illustrates a flowchart of a method 700 for forming an electronic device shown in FIG. 4 according to an embodiment of the present application. The electronic device formed with the method 700 includes the sensor assembly formed with the method 200 shown in FIG. 2, therefore, the method 700 may include the steps of the method 200 shown in FIG. 2.

Firstly, a substrate including a substrate front surface and a set of conductive pads on the substrate front surface is provided as shown in step 701. Further, a sensor assembly is provided with steps 702-706, which correspond to steps 201-205 shown in FIG. 2, respectively. After the sensor assembly is formed, it is mounted on the substrate as shown in step 707. It can be appreciated that, in some other embodiments, the sensor assembly may be firstly formed and the substrate may then be provided. In step 708, a set of connection wires is formed to electrically connect the set of conductive pads of the substrate with the interconnect area of the sensor, respectively; finally, in step 709, a second encapsulant layer is formed on top of the substrate to encapsulate the sensor assembly and the set of connection wires. The configuration of the substrate, the sensor assembly and the second encapsulant layer can be referred to the above illustration. Preferably, the second encapsulant layer is of a material different from the first encapsulant layer. In some embodiments, the above steps are performed on wafer level. That is, a substrate is a portion of a wafer, and multiple electronic devices are formed with the same wafer at the same time. Specifically, in some embodiments, after step 709, the wafer is mounted with solder balls at a bottom surface of the wafer, and each electronic device is singulated from the wafer thereafter.

The discussion herein included numerous illustrative figures that showed various portions of a heat spreader for use with a sensor assembly and method of forming thereof. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A sensor assembly, comprising:
a sensor, wherein the sensor comprises a sensor front surface comprising a sensor area and an interconnect area;
at least one filter layer formed on top of the sensor front surface, wherein the at least one filter layer covers and is in direct contact with the sensor area of the sensor;
a first encapsulant layer formed on top of the at least one filter layer, wherein the first encapsulant layer is transmissive to light; and
wherein the interconnect area is at least partially exposed from the at least one filter layer and the first encapsulant layer.

2. The sensor assembly according to claim 1, wherein the at least one filter layer comprises an optical filter film.

3. The sensor assembly according to claim 1, wherein the first encapsulant layer comprises a clear epoxy molding material.

4. The sensor assembly according to claim 1, wherein the at least one filter layer aligns vertically with the first encapsulant layer.

5. An electronic device, comprising:
a substrate comprising a substrate front surface and a set of conductive pads on the substrate front surface;
a sensor assembly mounted on the substrate front surface, the sensor assembly comprising:
a sensor, wherein the sensor comprises a sensor front surface comprising a sensor area and an interconnect area;
at least one filter layer formed on top of the sensor front surface, wherein the at least one filter layer covers and is in direct contact with the sensor area of the sensor;
a first encapsulant layer formed on top of the at least one filter layer, wherein the first encapsulant layer is transmissive to light; and
wherein the interconnect area is at least partially exposed from the at least one filter layer and the first encapsulant layer;
a set of connection wires for electrically connecting the set of conductive pads with the interconnect area, respectively; and
a second encapsulant layer formed on top of the substrate for encapsulating the sensor assembly and the set of connection wires.

6. The electronic device according to claim 5, further comprising:
a mother board on which the substrate is mounted, and
at least one electronic component mounted on the mother board.

7. The electronic device according to claim 6, wherein the at least one electronic component comprises a light source.

8. The electronic device according to claim 6, wherein the at least one electronic component has the same structure as the sensor assembly and is mounted on the mother board via another substrate.

9. The electronic device according to claim 5, wherein the second encapsulant layer is of a material different from the first encapsulant layer.

10. A method for forming a sensor assembly, comprising:
providing a sensor, wherein the sensor comprises a sensor front surface comprising a sensor area and an interconnect area;
forming a patterned photoresist layer on the sensor front surface, wherein the patterned photoresist layer at least partially covers the interconnect area of the sensor but exposes the sensor area;
forming at least one filter layer on top of the sensor front surface, wherein the at least one filter layer covers and is in direct contact with the sensor area of the sensor and the patterned photoresist layer;
forming a first encapsulant layer on top of the at least one filter layer, wherein the first encapsulant layer is transmissive to light; and
removing a portion of the first encapsulant layer, a portion of the at least one filter layer and the patterned photoresist layer to at least partially expose the interconnect area.

11. The method according to claim 10, wherein removing a portion of the first encapsulant layer, a portion of the at least one filter layer and the patterned photoresist layer comprising:
removing the portion of the first encapsulant layer and the portion of the at least one filter layer till the patterned photoresist layer; and
removing the remaining patterned photoresist layer.

12. The method according to claim 10, wherein the at least one filter layer comprises an optical filter film.

13. The method according to claim 10, wherein the first encapsulant layer comprises a clear epoxy molding material.

14. The method according to claim 10, wherein the at least one filter layer aligns vertically with the first encapsulant layer.
